(19) United States
(12) Patent Application Publication
(10) Pub. No.: US 2002/0120895 A1
(43) Pub. Date: Aug. 29, 2002

(54) Integrated circuit device having boundary scan register

(75) Inventor: Masahito Suzuki, Kawasaki (JP)

Correspondence Address: ARENT FOX KINTNER PLOTKIN & KAHN, PLLC, 1050 Connecticut Avenue, N.W., Suite 600, Washington, DC, 20036-5339, US

(73) Assignee: FUJITSU LIMITED

(21) Appl. No.: 09/891,310

(22) Filed: Jun. 27, 2001

(30) Foreign Application Priority Data
Feb. 2, 2001 (JP) 2001-26968

(51) Int. Cl. G01R 31/28

(52) U.S. Cl. 714/727

(57) ABSTRACT

An integrated circuit device having a plurality of input terminals comprises: a plurality of input buffers provided in correspondence to the plurality of input terminals; a pluralityof serialparallelconversioncircuitsforconverting, inserial-parallel, outputs of the inputbuffers, respectively; and a plurality of boundary scan registers which are provided in correspondence to each input terminal. The output of the input buffer is supplied to the serial parallel conversion circuit and the boundary scan register in parallel, to restrict a delay element between the input buffer and the serial parallel conversion circuit at a minimum.

### BACKGROUND OF THE INVENTION

1. Field of the Invention

The present invention relates generally to an integrated circuit device having boundary scan registers, and more particularly to an integrated circuit device provided with the boundary scan registers so as not to damage a high-speed operation of high-speed I/O cells (or macros).

2. Description of the Related Arts

Aboundary scan designing technique utilizing a boundary scan register (hereinafter called BSR) is a specification provided by IEEE in order to check a connection state between integrated circuit devices (hereinafter called LSI) mounted on a system board. According to this specification, the BSR is provided in correspondence to I/O cells (or macros) in the LSI, and these BSRs are connected in a chain manner to constitute ashift register, andascan-inandscan-outofdataarepossible. Such a boundary scan circuit is housed, so that it can be inspected whether or not an output signal of a first LSI agrees with an input signal of a second LSI connected to the first LSI, and it is possible to readily check a connection state between the LSIs on the system board.

Furthermore, when the boundary scan circuit is housed in correspondence to the I/O cells (or macros), it is possible to utilize the boundary scan circuit even for an operating test inside the LSI at a wafer stage. For an internal operating test at the wafer stage, a LSI tester is used. The number of probe terminals of the LSI tester has a fixed limit, but on the contrary, the number of I/O terminals of the recent LSI is, for example, 1000 pins, and has the tendency of increasing. With such the increase of the number of I/O terminals, there has occurred a case that a probe terminal of the LSI tester cannot be connected to all I/O terminals of a chip.

Then, by utilizing the boundary scan circuit, input test data are scanned in, a fixed internal operation is executed and an output test data is output by scanning out, so that even in a condition that the number of probe terminal of the LSI tester is smaller than the number of I/O terminals of the chip, an operating test with sufficient precision is possible.

FIG. 1 is a diagram showing a schematic configuration of a boundary scan circuit in a conventional LSI. In FIG. 1, two LSIs 10, 20 are mounted on a system board 1. Explaining a right side LSI 20, boundary scan registers (BSR) 25-1 to nareprovidedcorrespondingto input terminals 23-1 tonbetween input cells 24-1 to n as input buffers and an internal circuit 22, and these BSRs are connected ina longitudinal column between a test data input terminal TDI-2 and a test data output terminal TDO-2, as shown by a broken line, to configure a shift register. Similarly, boundary scan registers (BSR) 26-1 ton are provided corresponding to output terminals between output cells 27-1 to n as output buffers and the internal circuit 22, and these BSRs are connected in a longitudinal column between the test data input terminal TDI-2 and the test data output terminal TDO-2, to configure the shift register. BSRs 14-1 to n are similarly also provided between output cells 16-1 to n of the left side LSI 10 and an internal circuit 12, and are connected in a longitudinal column to configure the shift register.

In the first LSI 10 and second LSI 20, output terminals 18-1 to n of the first LSI are connected to input terminals 23-1 to n of the second LSI via a wire 2-1 to n in the system board 1. As mentioned above, it is possible to readily inspect this connection state by utilizing the boundary scan circuit. Specifically, predetermined test data are serially input from the test data input terminal TDI-1 of the first LSI 10, and test data are scanned into all the BSR 14-1 to n. The test data are input to the second LSI 20 via an output cell 16, an output terminal 18, and the connection wire 2-1 to n on the system board, respectively. Accordingly, when a connection state is regular, the scanned-in test data are input to the BSR 25-1 to n via an input terminal 23 of the second LSI 20 and an input cell 24.

Then, when it is checked whether or not, by utilizing a shift register function of the boundary scan circuit in the second LSI 20, all data of the BSR 25 are output from the test data output terminal TDO-2, and agree with the test data scanned in initially to the BSR 14, it can be inspected whether or not the connection state is regular.

In the same principle, the boundary scan circuit can be utilized even for the operating test inside the LSI. Explaining in the second LSI 20, the test data are initially input from the test data input terminal TDI-2, and are transferred to the BSR 25-1 to n in correspondence to the input terminal by the scan-in function of the boundary scan circuit. When the internal circuit 22 is performed a fixed internal logical process with respect to these test data, the process result data are provided and latched into the BSR 26-1 to n on an output side after a predetermined time period. Then, the latched process result data are output serially from a test data output terminal TDO-3 by a scan function.

In this manner, it is possible to input the test data in correspondence to all the input terminals, and to output the process result data in correspondence to all the output terminalswithoututilizingthe inputterminals 23 andanoutput terminals 28 of the second LSI 20. Accordingly, when probe terminals, which can correspond to a control signal terminal (not shown) of the LSI 20 and the test data input terminal TDI and output terminal TDO, are provided in an LSI tester, a wafer test with high precision can be carried out.

As described above, the boundary scan circuit is housed, whereby it is possible to readily inspect the connection state on the system board, and further to make the internal operating test with high precision by utilizing the LSI tester with a few probe terminals.

The recent computer system has a tendency to increase more frequencies of an operating clock, and I/O cells (I/O macros) of the LSI normally input the input signal of a few GHz, and have to output an output signal of the same frequency. In this case, the BSRprovided corresponding to the I/O terminal is a factor of hindering a high-speed operation of the I/O cells (or macros).

FIG. 2 is a circuit diagram showing the BSR provided intheinputcell(ormacro)ofahigh-speedLSI. Inahigh-speed system of about a few GHz, differential input signals are employed for the input signal, and the differential input signals are supplied to differential input pairs 23A, 23B of the LSI. The differential signals are shaped in waveforms by a differential input buffer 24A, and are converted into parallel signals 29 by a serial parallel conversion circuit 24B, and are supplied to the internal circuit as a signal of a lower-speed frequency. An input cell (or macro) corresponding to the high-speed input signal is constituted by the differential input buffer 24A and the serial parallel conversion circuit 24B.

The BSR configuring the boundary scan circuit is provided between the differential input buffer 24A and the serial parallel conversion circuit 24B. The BSR shown in FIG. 2 has a first selector circuit 34 for selecting any one of a system input SYSI and a test data input TDI; a flip-flop 30 for entrapping the selected data input; a latch circuit 32 for latching data entrapped by the flip-flop 30; and a second selector circuit 36 for selecting one of an output signal of the latch circuit and the signal SYSI on the system side.

The BSR is connected to a preceding stage BSR and a following stage BSR via the test data input TDI and the test data output TDO, to configure a shift register. The first selector circuit 34 is set to a “1” side, and the test data input TDI from the preceding stage BSR is entrapped into the flip-flop by a clock input according to a clock DR( data register) signal CDR, and the test data output TDO is transferred to the next stage BSR. Data entrapped into the flip-flop 30 are latched by the latch circuit 32 according to an update DR (data register) signal UDR. The latch data are output as a system output signal SYSO. Furthermore, the system input signal SYSI is entrapped into the flip-flop 30, and the entrapped system input signal is again transferred to the following stage BSR via the test data output TDO.

In combination with 3 types of operations as described above, various tests are carried out. The details will be described later. Furthermore, at the time of regular operations, the second selector circuit 36 is set to a “0” side according to a mode signal MODE, and an output of the differential input buffer 24A is input to the serial parallel conversion circuit 24B.

As the configuration of such the BSR is provided in correspondence to the input terminal at a prior stage to the serial parallel conversion, it matches the specification of IEEE, and can be defined by a standard boundary scan description language (BSDL) with respect to the differential input.

However, the second selector circuit 36 is inserted into between the differential input buffer 24A and the serial parallel conversion circuit 24B, so that the input signal is delayed. In order to accurately entrap the input signal of a few GHz and convert it in parallel to the signal of lower internal frequencies, an optimal circuit design is demanded between the differential input buffer 24A and the serial parallel conversion circuit 24B. However, as illustrated, when the BSR is provided between the both, the second selector circuit 36 is inserted therebetween at the minimum, and it is yet difficult to realize an optimized input cell (24A+24B) due to a delay at a few ages of the selector circuit 36 and an input load capacity of the first selector circuit 34.

FIG. 3 is a circuit diagram showing the BSR provided in the output cells (or macros) of the high-speed LSI. The BSR is provided between a parallel serial conversion circuit 27B and a differential output buffer 27A, on the output side. The configuration of this BSR has first, second selectors 44, 46, a flip-flop 40, and a latch circuit 42 in the same manner as FIG. 2. Even in this case, as the BSR is provided in correspondence to differential output terminals 28A, 28B, it is possible to describe by BSDL, and to inspect the connection state on the system board and inspect the internal circuit of the LSI.

However, in the same manner as in the input cells, it is difficult to conduct an optimal design of the high-speed output cells (or macros) comprising the parallel serial conversion circuit 27B and the differential output buffer 27A due to the input capacity of the first selector circuit 44 of the BSR, a delay of the second selector circuit 46, and the like.

In order to solve the above-mentioned drawbacks, it is considered that a plurality of the BSR are provided at the output of the serial parallel conversion circuit 24B at the input side of FIG. 2, and in the case, the plurality of BSRs for one input are defined, whereby it is impossible to describe such plural BSRs by the present boundary scan description language (BCDL). Furthermore, when a predetermined signal process is performed in the serial parallel conversion circuit 24B, it is yet difficult to correspond the data in the BSR to the input signal in one-to-one correspondence. The above problems is applicable to the output side of FIG. 3.

### SUMMARY OF THE INVENTION

It is therefore an object of the present invention to provide an integrated circuit device having the BSR in correspondence to the I/O terminal without hindering a high-speed operation of high-speed I/O cells.

In order to attain the above-mentioned objects, according to a first aspect of the present invention, an integrated circuit device having a plurality of input terminals comprises: a plurality of input buffers provided in correspondence to the plurality of input terminals; a plurality of serial parallel conversion circuits for converting, in serial-parallel, outputs of the input buffers, respectively; and a plurality of boundary scan registers which are provided in correspondence to each input terminal. The output of the input buffer is supplied to the serial parallel conversion circuit and the boundary scan register in parallel, to restrict a delay element between the input buffer and the serial parallel conversion circuit at a minimum.

Furthermore, a selector circuit for switching between a holding data signal of the boundary scan register and a normal input signal is disposed on the output sideofthe serial parallel conversioncircuit, sothatthehigh-speedinputcell (ormacro) comprising the input buffer and the serial parallel conversion circuit can be constituted by an optimal circuit. In this case, the selector circuits are provided with respect to a plurality of outputs of the serial parallel conversion circuit, respectively.

With the above-mentioned configuration, the boundary scan register selectively inputs an output of the input buffer and a test data input, and holds the input data, and the holding data or the outputs of the serial parallel conversion circuit is selectively output by the selector circuit. A plurality of boundary scan registers are serially connected to configure a shift register.

In order to attain the above-mentioned object, according to a second aspect of the present invention, an integrated circuit device having a plurality of output terminals comprises: a plurality of output buffers provided in correspondence to the plurality of output terminals; a pluralityof parallel serial conversion circuits forconverting, in parallel-serial, internal signals to provide the internal signals to the output buffer serially; and a plurality of boundary scan registers which are provided in correspondence to each output terminal. The internal signals are supplied to the parallel serial conversion circuit and the boundary scan register in parallel, to restrict the delay element between the parallel serial conversion circuit and the output buffer at a minimum.

Furthermore, a selector circuit for switching between a holding data signal of the boundary scan register and a normal output signal is disposed on the output side of the output buffer, so that the high-speed output cell (or macro) comprising the parallel serial conversion circuit and the output buffer can be constituted by an optimal circuit. In this case, when the output buffer has a plurality of outputs, a plurality of the selector circuits are provided in correspondence to each output.

With the above-mentioned configuration, the boundary scan register selectively inputs the internal signal and the test data input signal, and holds the input data, and the holding data or the outputs of the output buffer is selectively output by these lector circuit. A plurality of boundary scan registers are serially connected to configure a shift register.

The above input buffer, serial parallel conversion circuit, and boundary scan register configure an input macro by a hard macro. Similarly,the output buffer, parallel serial conversion circuit, and boundary scan register also configure an output macro by the hard macro.

According to the present invention, as the boundary scan registers are provided in each input terminal, or in each output terminal on the input side or output side, it is possible to define the registers by the BSDL, and further it is possible to provide the input macro and output macro which can correspond to the high-speed input signal or high-speed output signal.

### BRIEF DESCRIPTION OF THE DRAWINGS

FIG. 1 is a diagram showing a schematic configuration of a boundary scan circuit in a conventional LSI;

FIG. 2 is a circuit diagram showing BSR provided in an input cell (or macro) of a high-speed LSI;

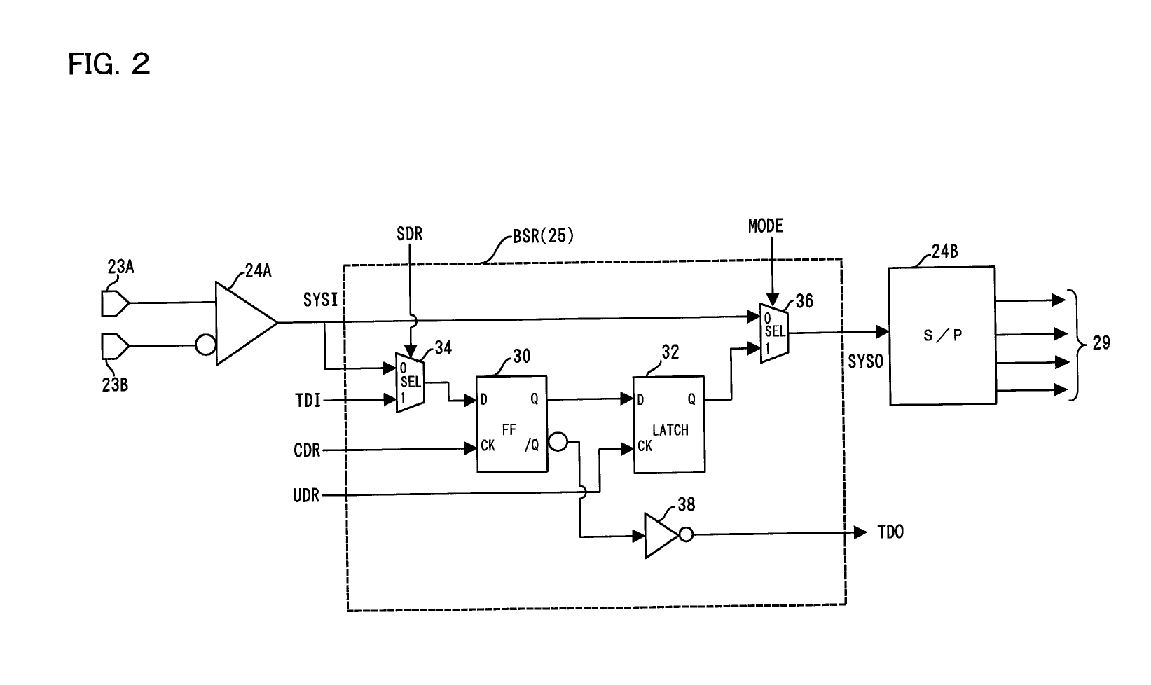

FIG. 3 is a circuit diagram showing the BSR provided in an output cell (or macro) of the high-speed LSI;

FIG. 4 is a diagram showing a boundary scan circuit on an input cell (or macro) side according to an embodiment of the present invention FIG. 5 is a detailed circuit diagram of an input macro of FIG. 4;

FIG. 6 is a timing chart illustration showing an operation of the BSR;

FIG. 7 is a diagram showing an example of a selector circuit in the BSR;

FIG. 8 is a diagram showing a boundary scan circuit on an output cell (or macro) side according to this embodiment;

FIG. 9 is a detailed circuit diagram of the output macro of FIG. 8;

FIG. 10 is a diagram showing an embodied circuit example of a differential output buffer 27A; and

FIG. 11 is a diagram showing an example of another output macro having the BSR.

### DESCRIPTION OF THE PREFERRED EMBODIMENT

An embodiment of the present invention will now be explained with reference to the drawings. However, such the embodiment does not limit a technical scope of the present invention.

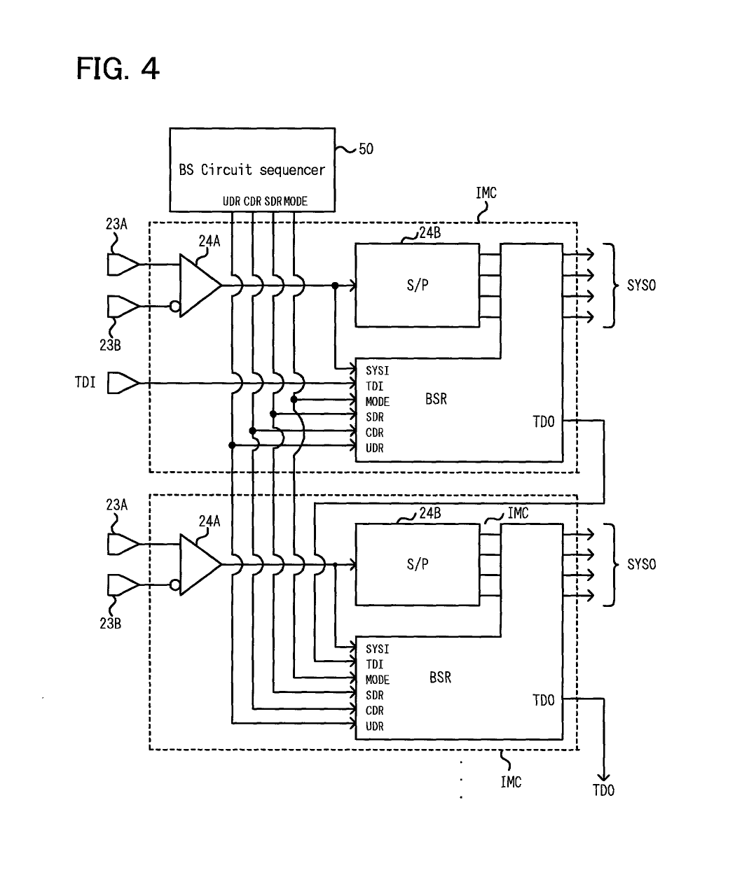

FIG. 4 is a diagram showing a boundary scan circuit on an input cell (or macro) side according to the embodiment of the present invention. In FIG. 4, an input cell (or macro) IMC in correspondence to two input terminal pairs is shown. In a high-speed computer system, an input signal having frequencies of a few GHz is input into the LSI. Accordingly, differential signals are utilized so as to more reliably input a high-speed signal. In FIG. 4, a pair of input terminals 23A, 23B to which differential input signals are supplied are provided, and an input macro IMC is provided in correspondence to this input terminal pair.

The input macro IMC has a differential input buffer 24A for receiving the differential input signals and a serial parallel conversion circuit 24B which inputs the output of the input buffer serially and converts in parallel to output. Furthermore, in the input macro IMC, the boundary scan register (BSR) is provided in parallel to a serial parallel conversion circuit 24B with respect to the output of the input buffer 24A. Accordingly, a system input terminal SYSI of BSR is connected to the output of the input buffer 24A. The system input SYSI or test data input TDI is selectively held by a flip-flop inside the BSR. Furthermore, the outputs of the serial parallel conversion circuit 24B or the data held by the BSR are selectively output into an internal circuit (not shown) as a system output SYSO.

A plurality of the BSRs provided in each of respective input terminals are connected serially via the test data input terminal TDI and test data output terminal TDO, to configure a shift register. A boundary scan (BS) circuit sequencer 50 controls a scan-in and scan-out operation, a latch operation, and a capture operation with respect to the BSR according to a mode signal MODE, a shift DR (data register) signal SDR, a clock DR signal CDR, an update DR signal UDR. These operations will be described later.

As shown in FIG. 4, the BSR and the serial parallel conversion circuit 24B are provided in parallel with respect to the output of the input buffer 24A, whereby only a minimum delay element is present between the input buffer 24A and the serial parallel conversion circuit 24B, so that it is possible to accurately perform an input process of a high-speed input signal by the differential input buffer 24A and the serial parallel conversion circuit 24B.

In an input macro IMC, the differential input buffer 24A and the serial parallel conversion circuit 24B within a cell library of ASIC are combined with the BSR, to configure it as an input soft macro. Alternatively, the serial parallel conversion circuit and the BSR are combined to configure it as an input hard macro in which a layout configuration is optimized from the beginning. Furthermore, the input hard macro having the input buffer, the serial parallel conversion circuit and the BSR may be configured. In either case, as only the minimum delay element is present between the input buffer 24A and the serial parallel conversion circuit 24B, a high-speed input macro can be configured.

FIG. 5 is a detailed circuit diagram of an input macro of FIG. 4. The same quotation numbers are affixed to the same elements as in FIG. 4. As mentioned above, the BSR and the serial parallel conversion circuit 24B are provided in parallel with respect to the output of the differential input buffer 24A. Namely, the output of the differential input buffer 24A is connected to one input terminal of first selector circuits 34 of the BSR as a system input SYSI. Accordingly, the first selector circuit 34 selects the output of the differential input buffer 24A or a test data input TDI in correspondence to a shift DR signal SDR, and supplies it as a data input of a flip-flop 30. The flip-flop 30 entraps the output of the first selector circuit 34 in response to a clock DR signal CDR, and outputs a non-inversion output Q and an inversion output /Q.

A latch circuit 32 latches the non-inversion output Q of the flip-flop 30 in response to an update DR signal UDR tooutputtheheldsignalQ. Furthermore,theinversionoutput /Q of the flip-flop 30 is output from a test data output terminal TDO via an inverter 38. This test data output terminal TDO is connected to the test data input terminal of a rear stage of BSR, as shown in FIG. 4.

The output Q of the latch circuit 32 is supplied to one input of second selector circuit groups 36-1 to 4, and four outputs of the serial parallel conversion circuit 24B are supplied to the other inputs. Any one of the output Q of the latch circuit 32 and the output of the serial parallel conversion circuit 24B is selected corresponding to a mode signal MODE, and is output to an internal circuit not shown as system outputs SYSO-1 to 4.

Incidentally, the serial parallel conversion circuit 24B inputs serially a high-speed input signal, and converts it in parallel into a lower speed internal input signal, and may have any signal processing functions in addition to a serial parallel conversion function.

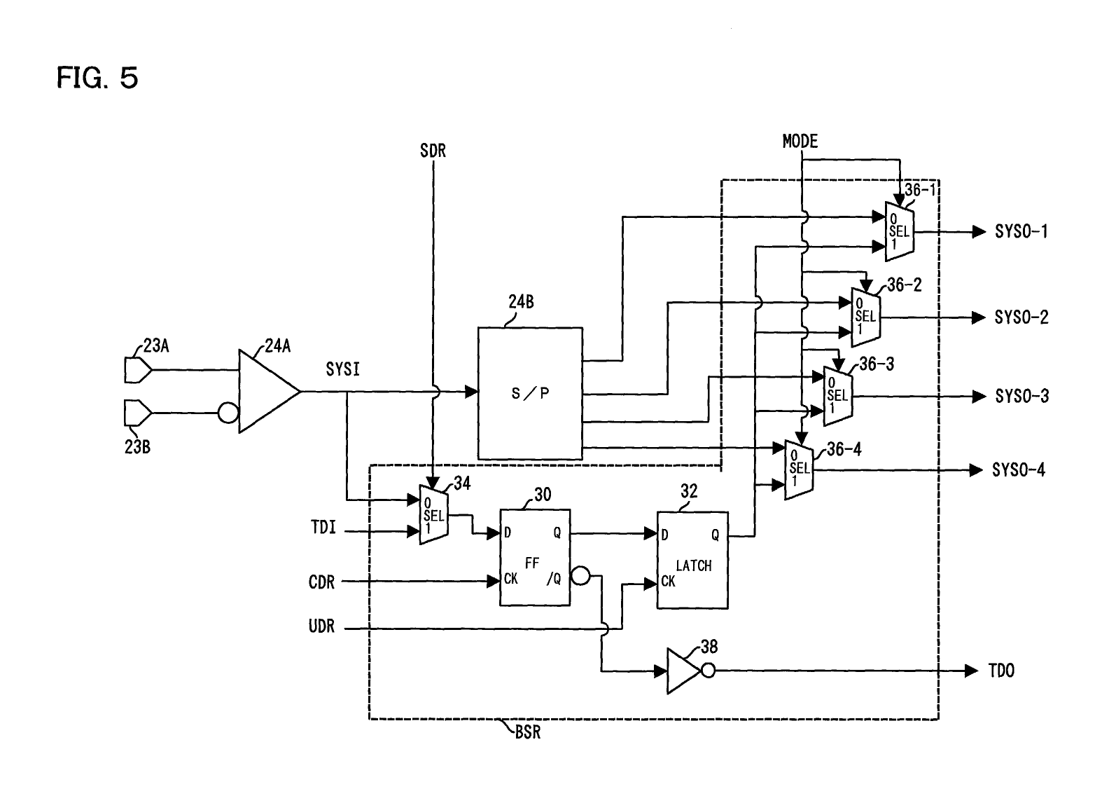

FIG. 6 is a timing chart showing an operation of the BSR. The mode signal MODE is a signal which activates a boundary scan circuit, to control switching of the second selector circuit group 36. When the mode signal MODE is in H level, the selector circuit group 36 selects a signal held by the BSR, and the signal is supplied to the internal circuit not shown as the system output SYSO.

Furthermore, a shift DR signal SDR controls the first selector circuit 34, and when the shift DR signal SDR is in H level, it selects a test data input TDI. In the state, when a clock DR signal CDR is in H level, and the test data input TDI is held in the flip-flop 30 in response thereto. As shown in FIG. 4, a plurality of the BSRs are serially connected via the test data input terminal TDI and the test data output terminal TDO of the BSR. Accordingly, the clock DR signal CDR is set to be continuously in H level, whereby the test data input TDI is transferred to the shift register of the serially connected BSRS, to scan in the test data. In FIG. 6, three test data DO, Dl, D2 are scanned in. These operations are scan-in and scan-out operations SCANIN/OUT (PA).

The input data held in the flip-flop 30 of each BSR is held in the latch circuit 32 in response to the H level of the update DR signal UDR. When held in the latch circuit 32, the data held by the latch circuit can thereafter be supplied to the internal circuit via the second selector circuit group 36 without being affected by the data held in the flip-flop. This is a latch operation LATCH (PB).

Furthermore, as shown in FIG. 6, when the shift DR signal SDR is set to L level, and the first selector circuit 34 is switchedtoasideof theinputbuffercircuit 24A, it is possible to hold the output data of the input buffer 24A in the flip-flop 30 in response to the clock DR signal CDR. This is a capture operation CAPTURE (PC), and this capture operation is an operation to be mainly utilized when a connection state between LSIs on a system board is inspected on an input terminal side.

Furthermore, the mode signal MODE is set to L level, and circuits other than the BSR are set to a normal state, and the clock DR signal CDR is set to H level, whereby the internal signal at the time of the regular operation can be entrapped into the flip-flop 30. This is also one of the capture operations.

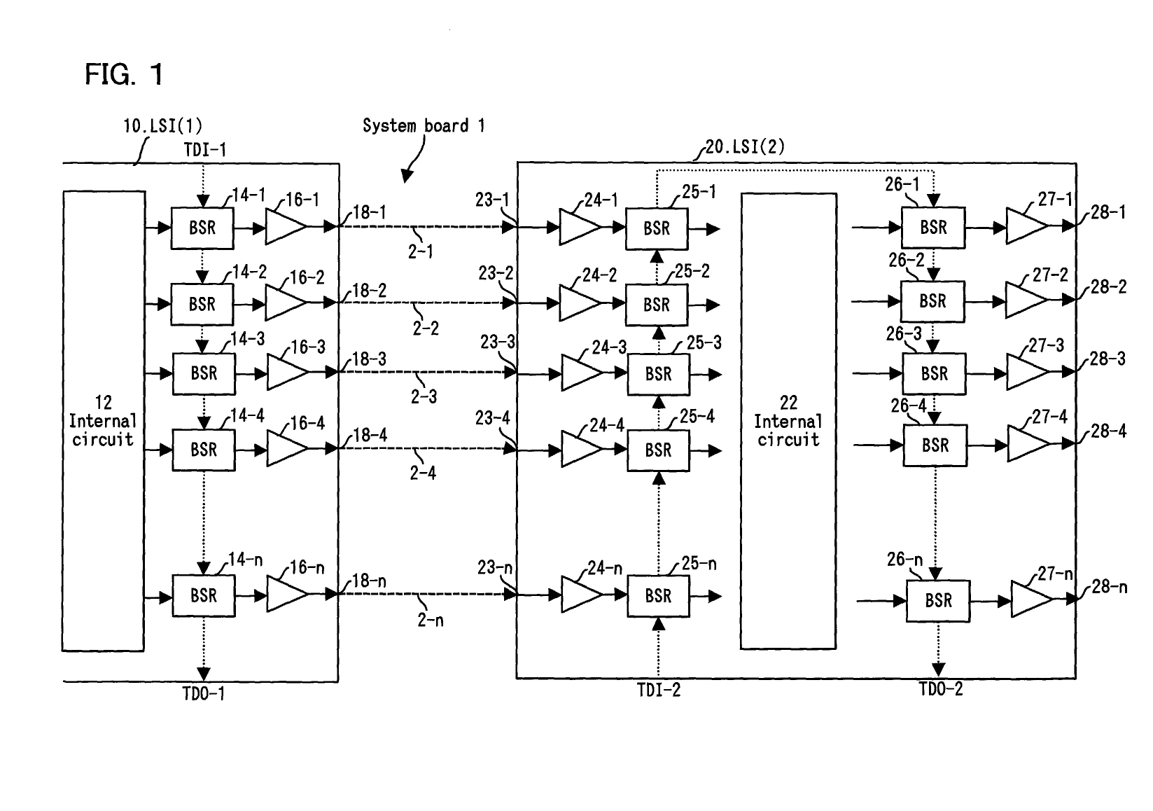

When the connection state on the system board is inspected, as shown in FIG. 1, the test data are scanned into the BSR of the boundary scan circuit in a preceding stage LSI 10, so that the test data are respectively latched by the latch operation, and thereafter the output of the input buffer 24A in a rear stage LSI 20 shown in FIGS. 4 and 5 is entrapped in the flip-flop 30 by the capture operation. The lastly entrapped test data are taken out from the test data output TDO to the outside by a scan-out operation. The first scanned-in test data are compared with the lastly scanned-out test data. Thus, it is inspected whether or not the connection state on the system board is normal.

When an operation test of the interior of the LSI is carried out, the test data are scanned in from the test data input terminal TDI in the plurality of BSRs shown in FIGS. 4 and 5, and thereafter the test data are latched by the latch circuit 32 inside each BSR by the latch operation, and are supplied to the internal circuit. After a predetermined internal operation is executed, the output of the internal circuit is subjected to the capture operation in the BSR on a side of the output terminal, and a test result signal is output to the outside by a scan-out operation. In this case, the scan-in and scan-out of the test data are possible without being connected to a normal input terminal or output terminal.

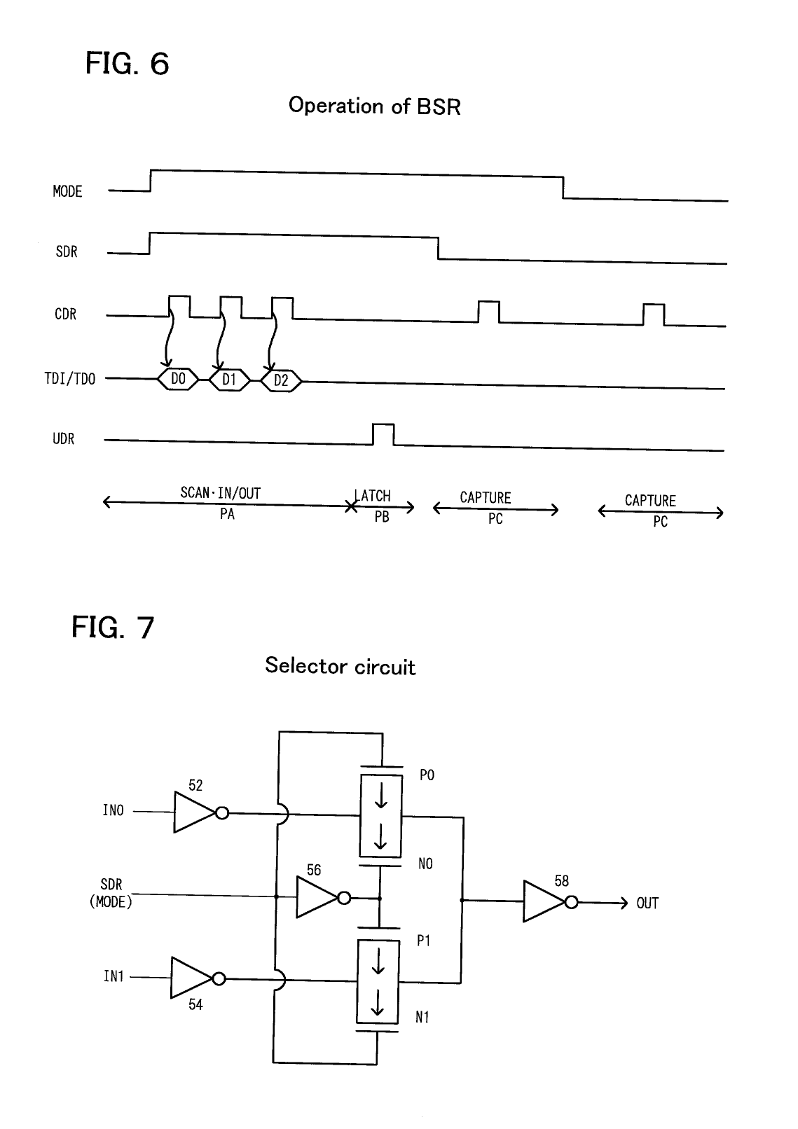

FIG. 7 is a diagram showing an example of a selector circuit in the BSR. The first and second selector circuits can be realized with the same configuration. However, FIG. 7 shows the first selector circuit. In the selector circuit, a first transfer gate comprising a P type transistor P0 and an N type transistor NO, and a second transfer gate comprising a P type transistor Pl and anNtype transistor Nl are controlled to be ON or OFF according to a control signal SDR. A first input INO is supplied to the first transfer gate via an inverter 52, and a second input IN1 is supplied to the second transfer gate via an inverter 54. An output of the transfer gate is output via an inverter 58. When the control signal SDR is in H level, the second transfer gate is conducted to select the second input IN1, and when the control signal SDR is in L level, and the first transfer gate is conducted to select the first input INO.

Incidentally, for the second selector circuit, a control signal is the mode signal MODE in the circuit configuration of FIG. 7. The remaining configuration is same as the example of FIG. 7.

As shown in FIG. 5, according to this embodiment, a connection with the input terminal of the selector circuit 34 is only present between the output terminal of the differential input buffer 24A and the input terminal of the serial parallel conversion circuit 24B, and a factor of an input signal delay is only its input load capacity. Accordingly, this is the minimum delay factor, which sufficiently fulfils a function as a high-speed input macro.

The second selector circuit group 36 is in series connected on an output side of the serial parallel conversion circuit 24B, and as a rear stage of the serial parallel conversion circuit 24B is a signal of a low-speed frequency of a few hundreds Hz band, such the delay factor does not affect a signal process so much.

Furthermore, as the above configuration can basically satisfies a specification of the boundary scan circuit in which the BSRs are provided in each input terminal, it is possible to define the BSR by the BSDL advocated by IEEE.

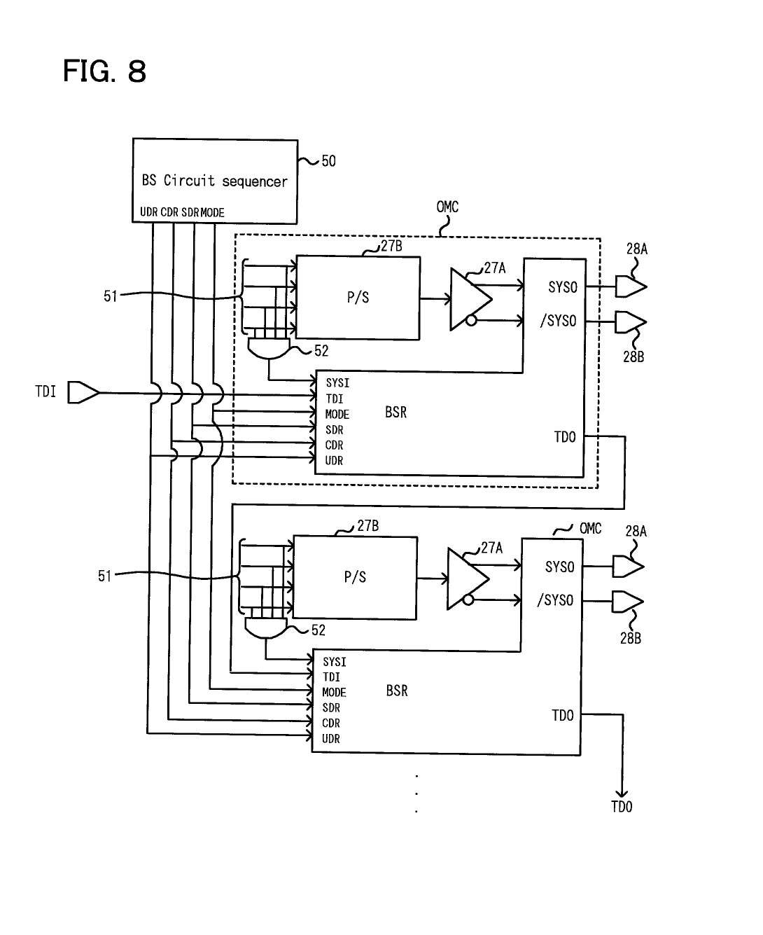

FIG. 8 is a diagram showing a boundary scan circuit on a side of the output cell (or macro) according to this embodiment. In FIG. 8, an output macro OMC is shown corresponding to two pairs of differential output terminals 28A, 28B. A plurality of internal signals 51 from the internal circuit not shown are supplied in parallel to the parallel serial conversion circuit 27B and the boundary scan register BSR, and the delay element between the parallel serial conversion circuit and the output buffer is restricted at a minimum. The output of the parallel serial conversion circuit 27B is directly connected to the differential output buffer 27A. Furthermore, the selector circuit for switching the output terminal of the latch circuit of the BSR and the outputs ignal of the differential output buffer 27A is disposed on the output side of the output buffer 27A. Accordingly,the high-speed output cell (or macro) comprising the parallel serial conversion circuit and the output buffer is configured by the optimizing circuit.

In the same manner as on the input terminal side, each BSR is serially connected via the test data input TDI and the test data output TDO, to configure the shift register. Furthermore, outputs of AND logic, OR logic, or exclusive OR of the plurality of internal signals are supplied to the system input SYSI of each BSR. Thus, it is expected that the precision in the operation test inside the LSI is lowered, but the BSR can be configured by a standard configuration in which one BSR is formed with respect to one output terminal.

In the boundary scan circuit configured by the BSR in this case, in the same manner as in the case of the input macro, ascan-in and scan-out operation, alatchoperationandacapture operation are controlled by a BSR circuit sequencer 50. In combination with these operations, as already mentioned, it is possible to realize a method for inspecting the connection state on the system board and amethod for testing the operations inside the LSI.

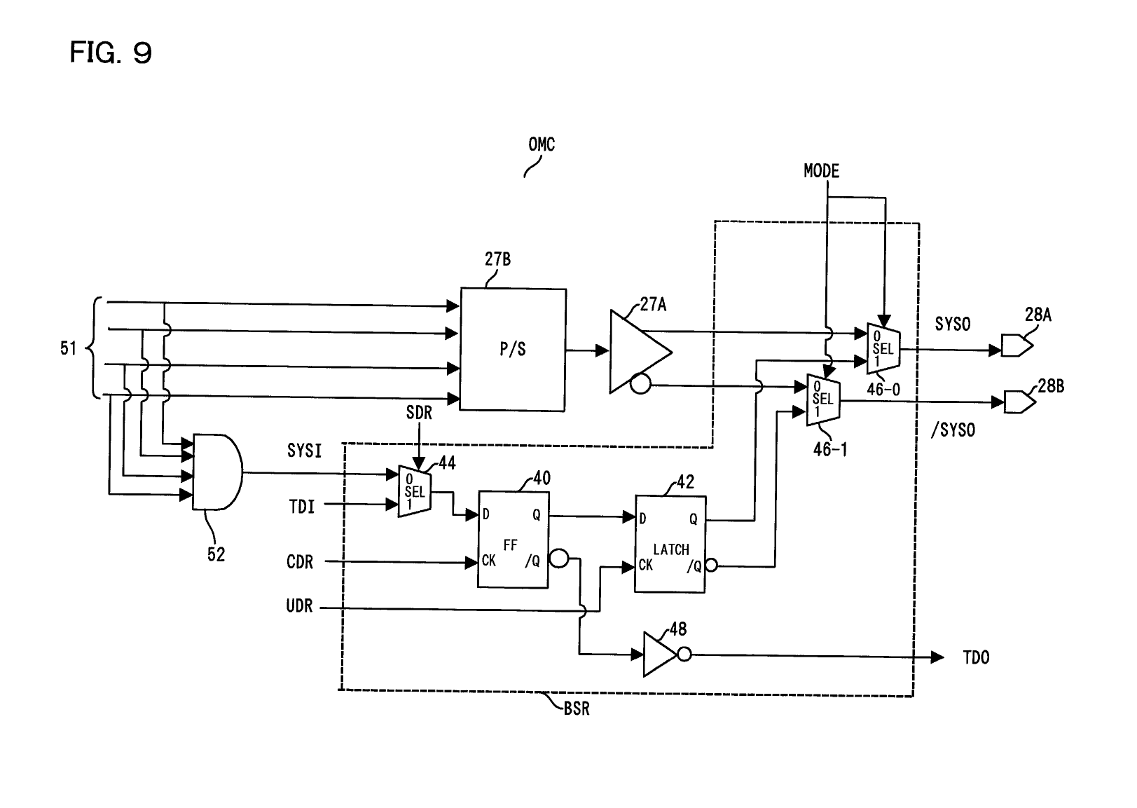

FIG. 9 is a detailed circuit diagram of the output macro of FIG. 8. A plurality of internal signals 51 to be output from the internal circuit not shown are input into the parallel serial conversion circuit 27B, and are converted into the high-speed output signal of, for example, a few GHz for output. This output is output as a differential output signal of a large amplitude by the differential output buffer 27A. Accordingly, the output on the output side of the differential output buffer 27A is a differential output signal of a high frequency at the large amplitude.

The plurality of internal signals 51 are summarized as a single signal by an AND gate 52, and the signal is input as the system input terminal SYSI of the BSR. An AND gate 52 may be an OR gate, and also may be a NAND gate, a NOR gate, or an EOR gate.

A first selector circuit 44 inside the BSR selects and input any one of the system input SYSI and the test data input TDI in correspondence to the shift DR signal SDR. The input data is entrapped into a flip-flop 40 in response to the clock DR signal CDR. The flip-flop 40 outputs the non-inversion output Q and the inversion output /Q. Furthermore, a latch circuit 42 latches the non-inversion output Q of the flip-flop 40 in response to the update driver signal UDR, and outputs the non-inversion output Q and the inversion output /Q into second selector circuit groups 46-0, 46-1. Furthermore, the inversion output /Q of the flip-flop 40 is output as the test data output TDO via an inverter 48.

The second selector circuit groups 46-0, 46-1 select any one of the differential output of the differential output buffer 27A and the differential outputs Q, /Q of the latch circuit 42 in correspondence to the mode signal MODE, and output into the output terminal pairs 28A, 28B as system outputs SYSO, /SYSO.

Anoperationofthe BSR inFig. 8,9 is the sameas explained in FIG. 6. Inotherwords, the test data input TDI is transferred to the flip-flop 40 in the plurality of BSRs by the scan-in and scan-out function, and the signals entrapped by the flip-flop of the plurality of BSRS are transferred from the test data output TDO. Furthermore, the data entrapped into the flip-flop 40 by the latch function are latched in the latch circuit 42, and signals after a logic process of the internal signal 51 can be entrapped into the flip-flop 40 by the capture operation.

In the output macro shown in FIGS. 8 and 9, the BSRs are provided in correspondence to the output terminal pairs. Accordingly, each BSR can be defined with respect to each output terminal by the BSDL standardized by IEEE. Additionally, as the delay factor between the parallel serial conversion circuit 27B for converting a low-speed internal signal into a high-speed output signal and the differential output buffer 27A is restricted at a minimum, both the circuits can be configured by optimizing so as to agree with the high-speed output signal. Furthermore, another processing function of internal signal 51 may be added to the parallel serial conversion circuit in addition to the parallel serial conversion function.

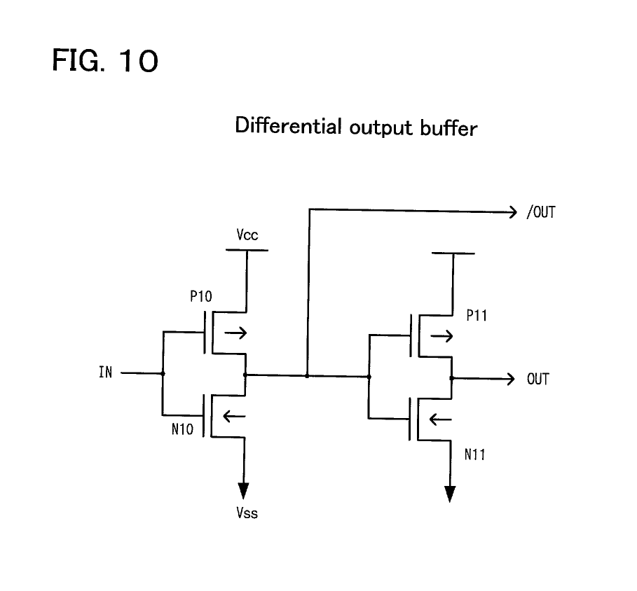

FIG. 10is adiagramshowingan exampleof the differential output buffer 27A. This differential output buffer is simply provided with two stages of CMOS inverters, and a first stage of inverter output is output as an inversion output /OUT, and a rear stage of inverter output is output as a non-inversion output OUT. P type transistors P10, P11 and N type transistors N10, N11 configuring each inverter are large-sized transistors, and the outputs OUT, /OUT have a signal waveform driven in a large amplitude.

Returning to FIG. 9, the connection terminal or gates of the BSR are not provided at all at the portion between the parallel serial conversion circuit 27B and the output buffer 27A which affects mostly the high-speed output signal process. Accordingly, there are no delay factors between the parallel serial conversion circuit 27B and the output buffer 27A, and both the circuits can be realized in a circuit configuration optimized. Furthermore,theoutputmacroOMCcanbeconfigured as a hard macro.

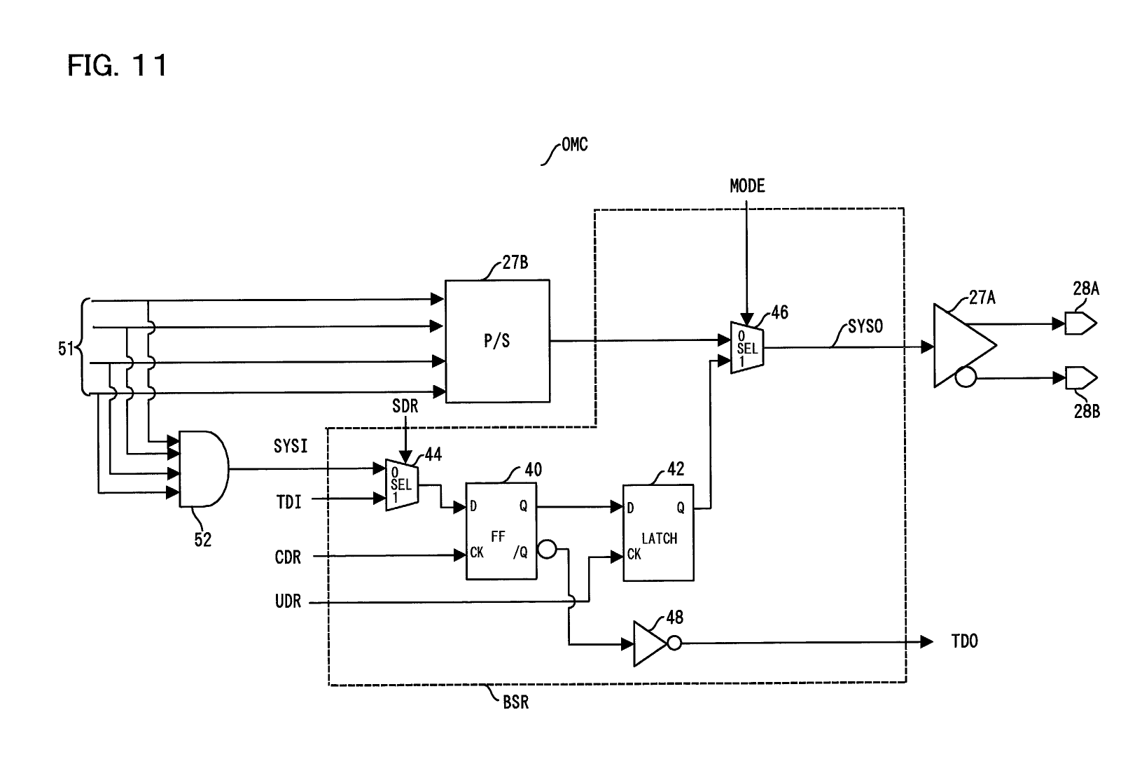

FIG. 11 is a diagram showing an example of another output macro having the BSR. Even in this example, the output signal 51 from the internal circuit is input in parallel into the parallel serial conversion circuit 27B and the BSR. A second selector circuit 46 in the BSR selects any one of the output of the parallel serial conversion circuit 27B and the output Q of a latch circuit 42 in correspondence to the mode signal MODE, and supplies it to the output buffer 27A. The differential output buffer 27A generates a differential output, and outputs it into the output terminal pairs 28A, 28B.

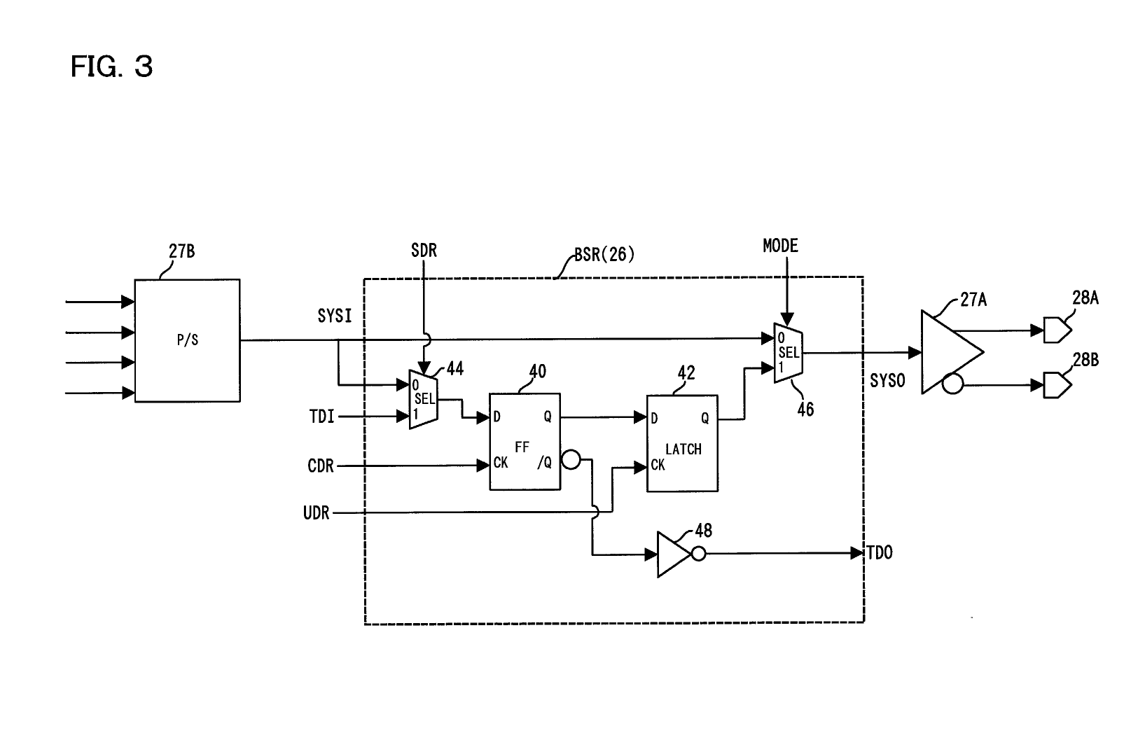

In this example, when compared with the prior art shown in FIG. 3, a first selector circuit 44 of the BSR is not connected to the portion between the parallel serial conversion circuit 27B and the output buffer 27A. The delay factors of the output signal of the parallel serial conversion circuit 27B are decreased. Accordingly, a delay characteristic between both the circuits 27B, 27A is improved.

It is confirmed that the example shown in FIG. 11 applies, for example, the case where the output signal is in a high-speed output of about a few hundreds MHz. Accordingly, this example cannot apply the high-speed output signal of a few GHz, but can apply the case of a middle-speed output signal which is rather slower than that.

According to the present invention, in the integrated circuit device complying to the high-speed input signal and output signal, the boundary scan circuit can be provided, and also it is possible to lessen a delay between the input buffer and the serial parallel conversion circuit in the input macro, and it is possible to lessen the delay between the parallel serial conversion circuit and the output buffer in the output macro. Accordingly, the boundary scan registers can be provided without impairing the high-speed signal process function of the input macro or the output macro.

What is claimed is:

1. An integrated circuit device having a plurality of input terminals, comprising:
a plurality of input buffers provided to the plurality of input terminals;
a plurality of serial parallel conversion circuits for converting, in serial-parallel, outputs of the input buffers, respectively; and
a plurality of boundary scan registers which input selectively an output of the input buffer or an input of a test data, holds the input data, and outputs selectively the held input data or an output of the serial parallel conversion circuit,
wherein the plurality of boundary scan registers are connected serially to constitute a shift register.

2. The integrated circuit device according to claim 1, wherein the boundary scan register comprises:
a first selector circuit for selectively inputting the output of the input buffer or the input of the test data; and
a second selector circuit for selectively outputting the held input data or the output of the serial parallel conversion circuit.

3. The integrated circuit device according to claim 2, wherein the serial parallel conversion circuit has a plurality of outputs, and the second selector circuits are provided in correspondence to the plurality of outputs of the serial parallel conversion circuit.

4. The integrated circuit device according to claim 1, whereintheinputterminals includedifferentialinputterminal pairs for inputting differential inputs, respectively, and the input buffer receives the differential input, and outputs an input of the serial parallel conversion circuit.

5. An integrated circuit device having a plurality of output terminals, comprising:
a plurality of parallel serial conversion circuits for converting, in parallel-serial, an internal signal;
a plurality of output buffers which are provided to the plurality of output terminals, and to which an output of the parallel serial conversion circuit is supplied; and
a plurality of boundary scan registers which selectively input the internal signal or an input of a test data, hold the input data, and selectively output the held input data or an output of the output buffer,
wherein the plurality of boundary scan registers are serially connected to constitute a shift register.

6. The integrated circuit device according to claim 5,
wherein the boundary scan register comprises:
a first selector circuit for selectively inputting the internal signal or the input of the test data; and
a second selector circuit for selectively outputting the held input data or the output of the output buffer.

7. The integrated circuit device according to claim 6, wherein the output buffer outputs a differential output, and the second selector circuit selectively outputs a complementary signal of the held input data or the differential output of the output buffer.

8. The integrated circuit device according to claim 6, wherein a plurality of the internal signals are input into the parallel serial conversion circuit, and an AND signal, OR signal, or an exclusive OR signal of the plurality of internal signals are input to the first selector circuit as the internal signal.

9. An integrated circuit device having a plurality of output terminals, comprising:
a plurality of parallel serial conversion circuits for converting, in parallel-serial, an internal signal;
a plurality of output buffers which are provided to the plurality of output terminals, and to which an output of the parallel serial conversion circuit is supplied;
a plurality of boundary scan registers which selectively input the internal signal or an input of the test data, hold the input data, and selectively output the held input data or an output of the parallel serial conversion circuit,
wherein the plurality of boundary scan registers are serially connected to constitute a shift register.

10. The integrated circuit device according to claim 9, wherein the boundary scan register comprises:
a first selector circuit for selectively inputting the internal signal or the input of the test data; and
a second selector circuit for selectively outputting the held input data or the output of the parallel serial conversion circuit.
